(19) United States
(12) Patent Application Publication
(10) Pub. No.: US 2025/0338724 A1
(43) Pub. Date: Oct. 30, 2025

(54) DISPLAY DEVICE

(71) Applicant: Japan Display Inc., Tokyo (JP)

(72) Inventors: Yozo NAKAYASU, Tokyo (JP); Sho YANAGISAWA, Tokyo (JP); Kazuyuki HARADA, Tokyo (JP)

(73) Assignee: Japan Display Inc., Tokyo (JP)

(21) Appl. No.: 19/093,299

(22) Filed: Mar. 28, 2025

(30) Foreign Application Priority Data
Apr. 25, 2024 (JP) 2024-071331

(51) Int. Cl. H10K 59/122; H10K 59/80; H10K 59/88

(52) U.S. Cl. CPC H10K 59/122; H10K 59/873; H10K 59/88

(57) ABSTRACT

According to one embodiment, a display device includes a display area including subpixels, a partition which includes a conductive lower portion and an upper portion, and surrounds each of the subpixels, a plurality of display elements which are provided in the subpixels, respectively, and each of which includes an organic layer which emits light based on application of voltage, and a plurality of sealing layers which are formed of an inorganic insulating material and cover the display elements, respectively. The partition includes a plurality of segments separated by a slit. At least one of the sealing layers overlaps at least part of the slit as seen in plan view.

### CROSS-REFERENCE TO RELATED APPLICATION

This application is based upon and claims the benefit of priority from Japanese Patent Application No. 2024-071331, filed Apr. 25, 2024, the entire contents of which are incorporated herein by reference.

### FIELD

Embodiments described herein relate generally to a display device.

### BACKGROUND

Recently, display devices to which an organic light emitting diode (OLED) is applied as a display element have been put into practical use. In this type of display devices, a technique for improving the yield is required.

### BRIEF DESCRIPTION OF THE DRAWINGS

FIG. 1 is a diagram showing a configuration example of a display device according to a first embodiment.

FIG. 2 is a schematic plan view showing an example of the layout of subpixels.

FIG. 3 is the schematic cross-sectional view of the display device along the III-III line of FIG. 2.

FIG. 4 is a schematic plan view showing some elements of the display device.

FIG. 5 is a schematic plan view showing an example of a configuration which can be applied to a partition and a first sealing layer according to the first embodiment.

FIG. 6 is the schematic cross-sectional view of the display device along the VI-VI line of FIG. 5.

FIG. 7 is the schematic cross-sectional view of the display device along the VII-VII line of FIG. 5.

FIG. 8 is a flowchart showing an example of the manufacturing method of the display device.

FIG. 9A is a schematic cross-sectional view showing the manufacturing process of the display device.

FIG. 9B is a schematic cross-sectional view showing a process following FIG. 9A.

FIG. 9C is a schematic cross-sectional view showing a process following FIG. 9B.

FIG. 9D is a schematic cross-sectional view showing a process following FIG. 9C.

FIG. 9E is a schematic cross-sectional view showing a process following FIG. 9D.

FIG. 9F is a schematic cross-sectional view showing a process following FIG. 9E.

FIG. 9G is a schematic cross-sectional view showing a process following FIG. 9F.

FIG. 9H is a schematic cross-sectional view showing a process following FIG. 9G.

FIG. 9I is a schematic cross-sectional view showing a process following FIG. 9H.

FIG. 9J is a schematic cross-sectional view showing a process following FIG. 9I.

FIG. 10 is a diagram for explaining the effect of the display device according to the first embodiment.

FIG. 11 is a diagram for explaining the effect of the display device according to the first embodiment.

FIG. 12 is a schematic cross-sectional view of a configuration according to a comparative example of the first embodiment.

FIG. 13 is a schematic cross-sectional view for explaining the effect of the first embodiment.

FIG. 14 is a schematic plan view showing a configuration according to a second embodiment.

FIG. 15 is a schematic plan view showing a configuration according to a third embodiment.

FIG. 16 is a schematic plan view showing a configuration according to a fourth embodiment.

FIG. 17 is the schematic cross-sectional view of the display device along the XVII-XVII line of FIG. 16.

FIG. 18 is the schematic cross-sectional view of the display device along the XVIII-XVIII line of FIG. 16.

FIG. 19 is a schematic plan view showing a configuration according to a fifth embodiment.

### DETAILED DESCRIPTION

In general, according to one embodiment, a display device comprises a display area including a plurality of subpixels, a partition which includes a conductive lower portion and an upper portion having an end portion protruding from a side surface of the lower portion, and surrounds each of the subpixels, a plurality of display elements which are provided in the subpixels, respectively, and each of which includes an organic layer which emits light based on application of voltage, and a plurality of sealing layers which are formed of an inorganic insulating material and cover the display elements, respectively. The partition includes a plurality of segments separated by a slit. At least one of the sealing layers overlaps at least part of the slit as seen in plan view.

According to another aspect of the embodiment, a display device comprises a first subpixel and a second subpixel, a partition which includes a conductive lower portion and an upper portion having an end portion protruding from a side surface of the lower portion, and surrounds the first subpixel and the second subpixel, first and second display elements which are provided in the first and second subpixels, respectively, and emit light exhibiting different colors, and first and second sealing layers which are formed of an inorganic insulating material and cover the first and second display elements, respectively. The partition includes a first segment located on the first subpixel side and a second segment located on the second subpixel side, and the first and second segments are separated by a slit. Part of the first sealing layer is located inside the slit.

These configurations can provide a display device such that the yield can be improved.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

### First Embodiment

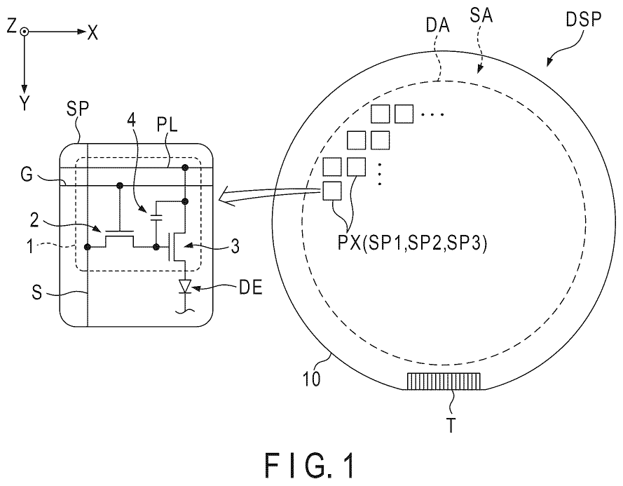

FIG. 1 is a diagram showing a configuration example of a display device DSP according to a first embodiment. The display device DSP comprises an insulating substrate 10. The substrate 10 has a display area DA which displays images, and a surrounding area SA located around the display area DA. The substrate 10 may be glass or a resinous film having flexibility.

In the embodiment, the substrate 10 and the display area DA are circular as seen in plan view. It should be noted that the shape of each of the substrate 10 and the display area DA in plan view is not limited to a circle and may be another shape such as a rectangle, a square or an oval.

The display area DA comprises a plurality of pixels PX arrayed in matrix in an X-direction and a Y-direction. Each pixel includes a plurality of subpixels SP which display different colors. This embodiment assumes a case where each pixel PX includes a blue subpixel SP1 (first subpixel), a green subpixel SP2 (second subpixel) and a red subpixel SP3 (third subpixel). Each pixel PX may include a subpixel SP which exhibits another color such as white in addition to subpixels SP1, SP2 and SP3 or instead of one of subpixels SP1, SP2 and SP3.

The display device DSP further comprises a terminal portion T provided in the surrounding area SA. For example, a flexible printed circuit which applies voltage and signals for driving the display device DSP is connected to the terminal portion T.

Each subpixel SP comprises a pixel circuit 1 and a display element DE driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

In the display area DA, a plurality of scanning lines G which supply scanning signals to the pixel circuit 1 of each subpixel SP, a plurality of signal lines S which supply video signals to the pixel circuit 1 of each subpixel SP and a plurality of power lines PL are provided. In the example of FIG. 1, the scanning lines G and the power lines PL extend in the X-direction, and the signal lines S extend in the Y-direction.

The gate electrode of the pixel switch 2 is connected to the scanning line G. One of the source electrode and drain electrode of the pixel switch 2 is connected to the signal line S. The other one is connected to the gate electrode of the drive transistor 3 and the capacitor 4. In the drive transistor 3, one of the source electrode and the drain electrode is connected to the power line PL and the capacitor 4, and the other one is connected to the display element DE.

It should be noted that the configuration of the pixel circuit 1 is not limited to the example shown in the figure. For example, the pixel circuit 1 may comprise more thin-film transistors and capacitors.

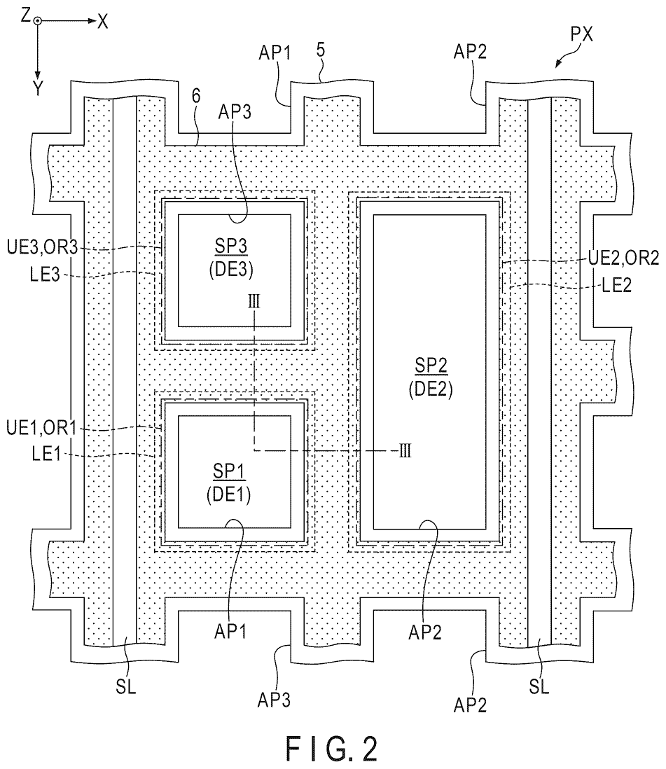

FIG. 2 is a schematic plan view showing an example of the layout of subpixels SP1, SP2 and SP3 constituting a pixel PX. In the example of FIG. 2, subpixels SP1 and SP3 are arranged in the Y-direction. Each of subpixels SP1 and SP3 is adjacent to subpixel SP2 in the X-direction.

When subpixels SP1, SP2 and SP3 are provided in line with this layout, a column in which subpixels SP1 and SP3 are alternately provided in the Y-direction and a column in which a plurality of subpixels SP2 are repeatedly provided in the Y-direction are formed in the display area DA. These columns are alternately arranged in the X-direction. It should be noted that the layout of subpixels SP1, SP2 and SP3 is not limited to the example of FIG. 2.

A rib layer 5 is provided in the display area DA. The rib layer 5 has pixel apertures AP1, AP2 and AP3 in subpixels SP1, SP2 and SP3, respectively. In the example of FIG. 2, the pixel apertures AP1 and AP3 are rectangles whose areas are equal to each other. The pixel aperture AP2 is a rectangle which is elongated in the Y-direction relative to the pixel apertures AP1 and AP3. It should be noted that the shape of the pixel aperture AP1, AP2 or AP3 is not limited to this example.

Subpixel SP1 comprises a lower electrode LE1, an upper electrode UE1 and an organic layer OR1 overlapping the pixel aperture AP1. Subpixel SP2 comprises a lower electrode LE2, an upper electrode UE2 and an organic layer OR2 overlapping the pixel aperture AP2. Subpixel SP3 comprises a lower electrode LE3, an upper electrode UE3 and an organic layer OR3 overlapping the pixel aperture AP3.

Of the lower electrode LE1, the upper electrode UE1 and the organic layer OR1, the portions which overlap the pixel aperture AP1 constitute the display element (first display element) DE1 of subpixel SP1. Of the lower electrode LE2, the upper electrode UE2 and the organic layer OR2, the portions which overlap the pixel aperture AP2 constitute the display element (second display element) DE2 of subpixel SP2. Of the lower electrode LE3, the upper electrode UE3 and the organic layer OR3, the portions which overlap the pixel aperture AP3 constitute the display element (third display element) DE3 of subpixel SP3. Each of the display elements DE1, DE2 and DE3 may further include a cap layer as described later. The rib layer 5 surrounds each of these display elements DE1, DE2 and DE3.

A conductive partition 6 is provided above the rib layer 5. The partition 6 functions as lines which apply common voltage to the upper electrodes UE1, UE2 and UE3. The partition 6 overlaps the rib layer 5 as a whole and has a planar shape similar to that of the rib layer 5. The partition 6 surrounds subpixels SP1, SP2 and SP3.

As described in detail later, the partition 6 has a plurality of slits SL. In the example of FIG. 2, each slit SL extends in the Y-direction. For example, subpixels SP1, SP2 and SP3 constituting one pixel PX is provided between two slits SL which are adjacent to each other in the X-direction.

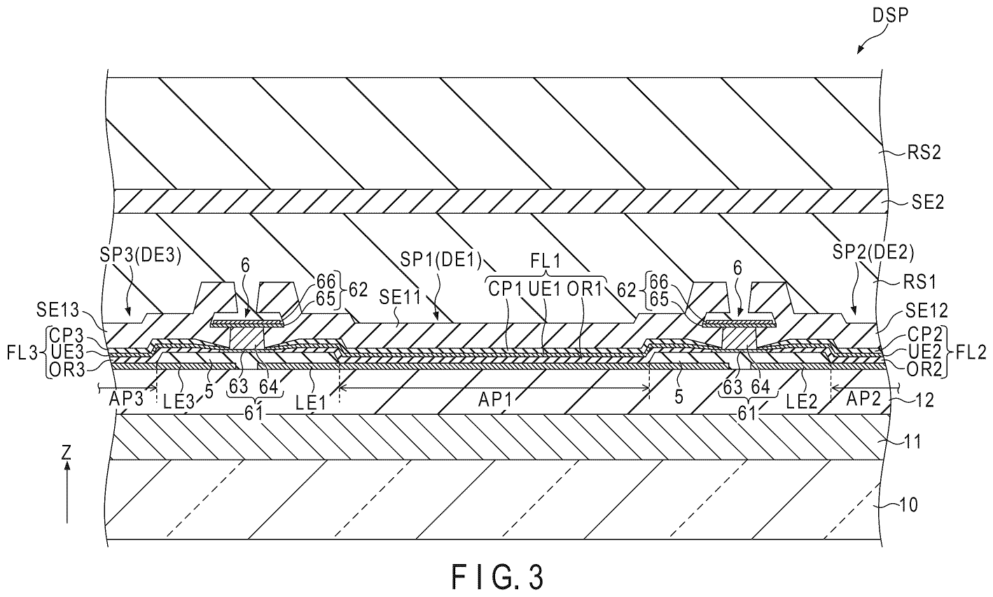

FIG. 3 is the schematic cross-sectional view of the display device DSP along the III-III line of FIG. 2. A circuit layer 11 is provided on the substrate 10 described above. The circuit layer 11 includes various circuits and lines such as the pixel circuits 1, scanning lines G, signal lines S and power lines PL shown in FIG. 1. The circuit layer 11 is covered with an organic insulating layer 12. The organic insulating layer 12 functions as a planarization film which planarizes the irregularities formed by the circuit layer 11.

The lower electrodes LE1, LE2 and LE3 are provided on the organic insulating layer 12. The rib layer 5 is provided on the organic insulating layer 12 and the lower electrodes LE1, LE2 and LE3. The end portions of the lower electrodes LE1, LE2 and LE3 are covered with the rib layer 5. Although not shown in the section of FIG. 3, the lower electrodes LE1, LE2 and LE3 are connected to the respective pixel circuits 1 of the circuit layer 11 through respective contact holes provided in the organic insulating layer 12.

The partition 6 includes a conductive lower portion 61 provided on the rib layer 5 and an upper portion 62 provided on the lower portion 61. The upper portion 62 has a width greater than that of the lower portion 61. By this configuration, the both end portions of the upper portion 62 protrude relative to the side surfaces of the lower portion 61. This shape of the partition 6 is called an overhang shape.

In the example of FIG. 3, the lower portion 61 has a bottom layer 63 provided on the rib layer 5, and a stem layer 64 provided on the bottom layer 63. For example, the bottom layer 63 is formed so as to be thinner than the stem layer 64. In the example of FIG. 3, the both end portions of the bottom layer 63 protrude from the side surfaces of the stem layer 64.

In the example of FIG. 3, the upper portion 62 comprises a first top layer 65, and a second top layer 66 provided on the first top layer 65. For example, the width of the second top layer 66 is slightly less than that of the first top layer 65. It should be noted that the configuration is not limited to this example. The first top layer 65 and the second top layer 66 may have the same width.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2 and UE3 are in contact with the lower portions 61 of the partition 6.

The display element DE1 includes a cap layer CP1 which covers the upper electrode UE1. The display element DE2 includes a cap layer CP2 which covers the upper electrode UE2. The display element DE3 includes a cap layer CP3 which covers the upper electrode UE3. The cap layers CP1, CP2 and CP3 function as optical adjustment layers which improve the extraction efficiency of the light emitted from the organic layers OR1, OR2 and OR3, respectively.

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

Sealing layers (first to third sealing layers) SE11, SE12 and SE13 are provided in subpixels SP1, SP2 and SP3, respectively. The sealing layer SE11 continuously covers the display element DE1 and the partition 6 around the display element DE1. The sealing layer SE12 continuously covers the display element DE2 and the partition 6 around the display element DE2. The sealing layer SE13 continuously covers the display element DE3 and the partition 6 around the display element DE3.

In the example of FIG. 3, the sealing layer SE11 located on the partition 6 between subpixels SP1 and SP2 is spaced apart from the sealing layer SE12 located on this partition 6. The sealing layer SE11 located on the partition 6 between subpixels SP1 and SP3 is spaced apart from the sealing layer SE13 located on this partition 6. It should be noted that two of the sealing layers SE11, SE12 and SE13 may be in contact with each other above the partition 6.

For example, a gap is formed between each of the sealing layers SE11, SE12 and SE13 and the upper portion 62 of the partition 6. The stacked films FL1, FL2 and FL3 may be provided in at least part of these gaps.

The sealing layers SE11, SE12 and SE13 are covered with a resin layer RS1. The resin layer RS1 is covered with a sealing layer SE2. The sealing layer SE2 is covered with a resin layer RS2. The resin layers RS1 and RS2 and the sealing layer SE2 are continuously provided in at least the entire display area DA and partly extend to the surrounding area SA.

A cover member such as a polarizer, a touch panel, a protective film or a cover glass may be further provided above the resin layer RS2. This cover member may be attached to the resin layer RS2 via, for example, an adhesive layer such as an optical clear adhesive (OCA). The electrodes which constitute the touch panel described above may be provided on the sealing layer SE2.

The organic insulating layer 12 is formed of an organic insulating material such as polyimide. Each of the rib layer 5 and the sealing layers SE11, SE12, SE13 and SE2 is formed of an inorganic insulating material such as silicon nitride (SiNx), silicon oxide (SiOx) or silicon oxynitride (SiON). For example, the rib layer 5 is formed of silicon oxynitride, and each of the sealing layers SE11, SE12, SE13 and SE2 is formed of silicon nitride. Each of the resin layers RS1 and RS2 is formed of, for example, a resinous material (organic insulating material) such as epoxy resin or acrylic resin.

Each of the lower electrodes LE1, LE2 and LE3 has a reflective layer formed of, for example, silver, and a pair of conductive oxide layers covering the upper and lower surfaces of the reflective layer. Each of the conductive oxide layers can be formed of, for example, a transparent conductive oxide such as indium tin oxide (ITO), indium zinc oxide (IZO) or indium gallium zinc oxide (IGZO).

Each of the upper electrodes UE1, UE2 and UE3 is formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

Each of the organic layers OR1, OR2 and OR3 consists of a plurality of thin films including a light emitting layer. For example, each of the organic layers OR1, OR2 and OR3 comprises a structure in which a hole injection layer, a hole transport layer, an electron blocking layer, a light emitting layer, a hole blocking layer, an electron transport layer and an electron injection layer are stacked in order in a Z-direction. It should be noted that each of the organic layers OR1, OR2 and OR3 may comprise another structure such as a tandem structure including a plurality of light emitting layers.

Each of the cap layers CP1, CP2 and CP3 comprises, for example, a multilayer structure in which a plurality of transparent layers are stacked. These transparent layers could include a layer formed of an inorganic material and a layer formed of an organic material. The transparent layers have refractive indices different from each other. For example, the refractive indices of these transparent layers are different from the refractive indices of the upper electrodes UE1, UE2 and UE3 and the refractive indices of the sealing layers SE11, SE12 and SE13. It should be noted that at least one of the cap layers CP1, CP2 and CP3 may be omitted.

Each of the bottom layer 63 and stem layer 64 of the partition 6 is formed of a metal material. For the metal material of the bottom layer 63, for example, molybdenum, titanium, titanium nitride (TiN), a molybdenum-tungsten alloy (MoW) or a molybdenum-niobium alloy (MoNb) can be used. For the metal material of the stem layer 64, for example, aluminum, an aluminum-neodymium alloy (AlNd), an aluminum-yttrium alloy (AlY) or an aluminum-silicon alloy (AlSi) can be used. It should be noted that the stem layer 64 may be formed of an insulating material.

The first top layer 65 of the partition 6 is formed of, for example, a metal material. The second top layer 66 of the partition 6 is formed of, for example, a conductive oxide. For the metal material forming the first top layer 65, for example, titanium, titanium nitride, molybdenum, tungsten, a molybdenum-tungsten alloy or a molybdenum-niobium alloy can be used. For the conductive oxide forming the second top layer 66, for example, ITO or IZO can be used. It should be noted that the upper portion 62 may comprise three or more layers or may consist of a single layer. The upper portion 62 may further include a layer formed of an insulating material.

Common voltage is applied to the partition 6. This common voltage is applied to each of the upper electrodes UE1, UE2 and UE3 which are in contact with the lower portions 61. Pixel voltage is applied to the lower electrodes LE1, LE2 and LE3 through the pixel circuits 1 provided in subpixels SP1, SP2 and SP3, respectively, based on the video signals of the signal lines S.

The organic layers OR1, OR2 and OR3 emit light based on the application of voltage. Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2 and OR3 may emit light exhibiting the same color (for example, white). In this case, the display device DSP may comprise color filters which convert the light emitted from the light emitting layers into light exhibiting colors corresponding to subpixels SP1, SP2 and SP3. The display device DSP may comprise a layer including quantum dots which generate light exhibiting colors corresponding to subpixels SP1, SP2 and SP3 by the excitation caused by the light emitted from the light emitting layers.

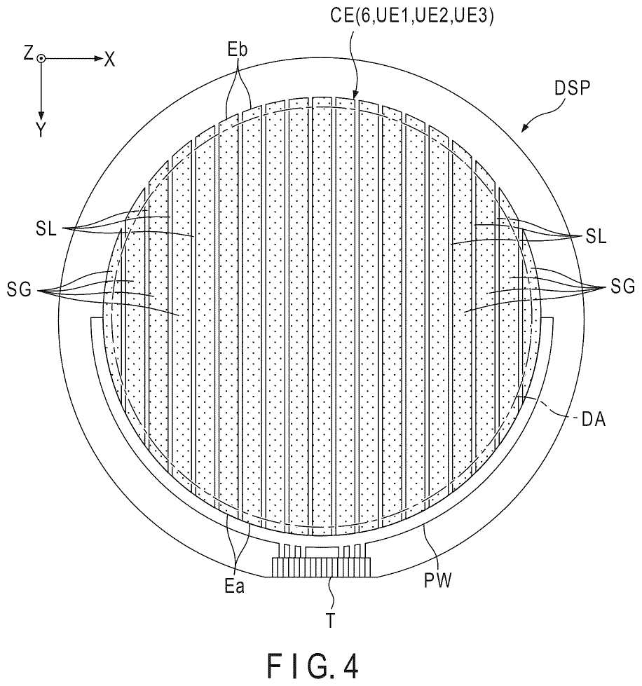

FIG. 4 is a schematic plan view showing some elements of the display device DSP. The partition 6 and the upper electrodes UE1, UE2 and UE3 constitute a common electrode CE which applies common voltage to the display elements DE1, DE2 and DE3. The common electrode CE is, for example, circular, and overlaps the display area DA as a whole.

The common electrode CE has a plurality of slits SL. At least one end of each of the slits SL reaches the outer edge of the common electrode CE (the outline in plan view). In the example of FIG. 4, both ends of each slit SL reach the outer edge of the common electrode CE. By this configuration, the common electrode CE is divided into a plurality of segments SG which are spaced apart from each other via the slits SL.

In the example of FIG. 4, each slit SL extends in the Y-direction. As another example, each slit SL may extend parallel to the X-direction. The number of slits SL provided in the common electrode CE is not particularly limited. For example, at least 17 slits SL are provided, thereby dividing the common electrode CE into at least 18 segments.

The interval of the slits SL in the X-direction is, for example, constant. In this case, the widths of the segments SG in the X-direction are also constant. As another example, the interval of the slits SL or the widths of the segments SG may not be constant.

Each segment SG has a first end portion Ea and a second end portion Eb in the extension direction of the slits SL (in this embodiment, the Y-direction). Each first end portion Ea is connected to a power supply line PW provided in the surrounding area SA. The power supply line PW is connected to the terminal portion T. Common voltage is applied to each segment SG from the terminal portion T via the power supply line PW. In the example of FIG. 4, the second end portions Eb of the segments SG are spaced apart from each other via the slits SL and are not connected by a conductive member such as the power supply line PW.

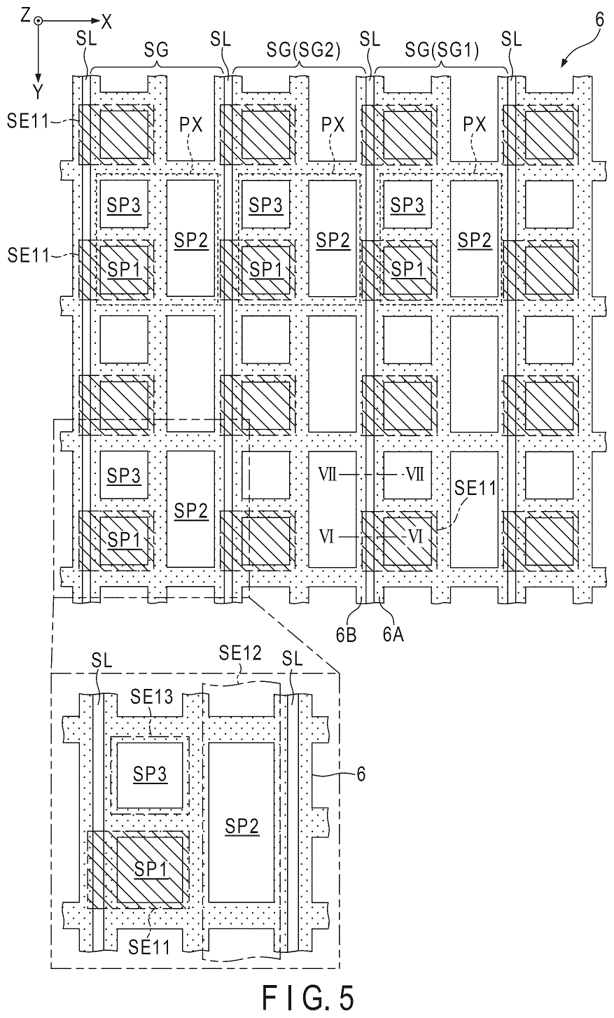

FIG. 5 is a schematic plan view showing an example of a configuration which can be applied to the partition 6 and the first sealing layer SE11 according to the present embodiment. It should be noted that other elements such as the sealing layers SE12 and SE13 are omitted.

The slits SL are provided in portions extending parallel to the Y-direction in the partition 6. Specifically, in the example of FIG. 5, each slit SL is provided in the portion located between pixels PX which are adjacent to each other in the X-direction in the partition 6. However, the form of the slits SL is not limited to this example. For example, two or more pixels PX may be arranged between adjacent slits SL in the X-direction.

As shown in FIG. 5, each sealing layer SE11 covers subpixel SP1 and also overlaps the slit SL. Specifically, each sealing layer SE11 is a rectangle which is elongated in the X-direction, and intersects with the slit SL as seen in plan view. It should be noted that some sealing layers SE11 may not overlap the slits SL.

In the lower part of FIG. 5, an example of the layout form of the sealing layers SE12 and SE13 is shown. In this example, neither the sealing layer SE12 nor the sealing layer SE13 overlaps the slits SL. In other words, the sealing layers SE12 and SE13 are spaced apart from the slits SL as seen in plan view. It should be noted that part of the sealing layers SE12 and SE13 provided in the display area DA may overlap the slits SL.

The sealing layer SE12 is, for example, continuously formed over a plurality of subpixels SP2 arranged in the Y-direction. As another example, the sealing layer SE12 may be formed for each subpixel SP2.

Here, as shown in FIG. 5, this specification focuses attention on two segments (first and second segments) SG1 and SG2 separated by the slit SL. The segment SG1 has a partition (first partition) 6A along the slit SL. The segment SG2 has a partition (second partition) 6B along the slit SL. Both the partition 6A and the partition 6B extend in the Y-direction.

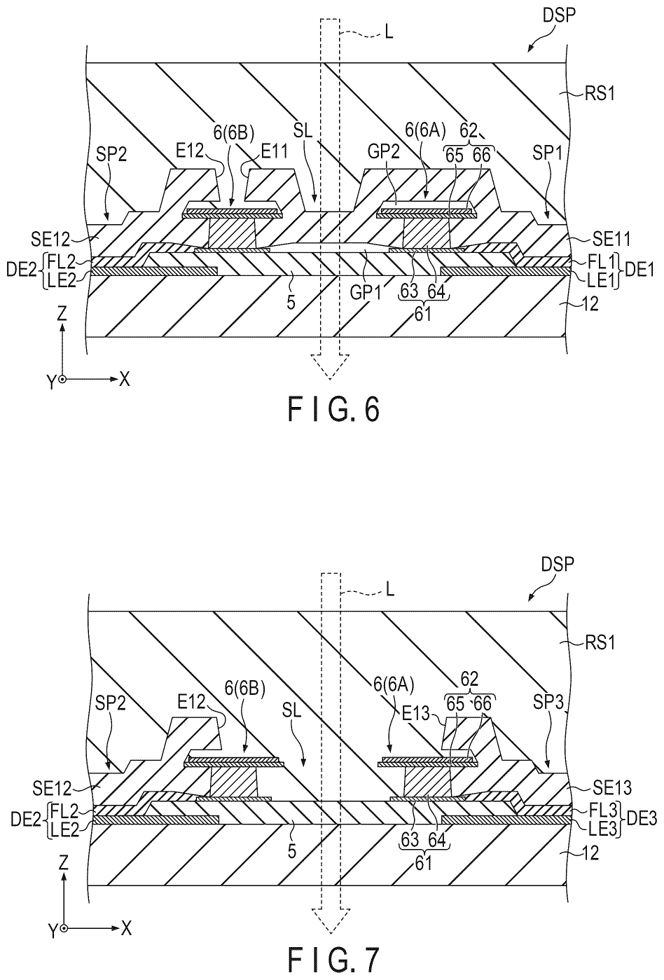

FIG. 6 is the schematic cross-sectional view of the display device DSP along the VI-VI line of FIG. 5. FIG. 7 is the schematic cross-sectional view of the display device DSP along the VII-VII line of FIG. 5. In these figures, the elements located under the organic insulating layer 12 and the elements located above the resin layer RS1 are omitted.

As shown in FIG. 6, each of the partitions 6A and 6B has an overhang shape in which the both end portions of the upper portion 62 protrude relative to the side surfaces of the lower portion 61 (the side surfaces of the stem layer 64). In addition, in the example of FIG. 6, in the slit SL, similarly, the end portion of the bottom layer 63 of each of the partitions 6A and 6B protrudes from the side surface of the stem layer 64.

In the section of FIG. 6, the sealing layer SE11 continuously covers the display element DE1 of subpixel SP1, the partition 6A and the slit SL. Further, the sealing layer SE11 is partly located inside the slit SL. In other words, at least part of the slit SL is filled with the sealing layer SE11.

An end portion E11 of the sealing layer SE11 is located above the partition 6B. An end portion E12 of the sealing layer SE12 of subpixel SP2 is also located above the partition 6B. These end portions E11 and E12 are spaced apart from each other in the X-direction.

For example, the rib layer 5 is not open in the slit SL. In this case, the slit SL overlaps the rib layer 5 as a whole.

In the example of FIG. 6, a gap GP1 is formed under the sealing layer SE11 which covers the slit SL. The gap GP1 corresponds to a void located between the upper surface of the rib layer 5 and the lower surface of the sealing layer SE11. A gap GP2 is formed under the sealing layer SE11 above the partition 6A. The gap GP2 corresponds to a void located between the upper portion 62 of the partition 6A and the lower surface of the sealing layer SE11. The stacked film FL1 may be present in part of these gaps GP1 and GP2.

In the section of FIG. 7, the sealing layer SE11 is not provided in the slit SL. The slit SL is filled with the resin layer RS1. The resin layer RS1 covers the rib layer 5 in the slit SL.

An end portion E13 of the sealing layer SE13 of subpixel SP3 is located above the partition 6A. The end portion E12 of the sealing layer SE12 is located above the partition 6B in a manner similar to that of the example of FIG. 6.

None of the lower electrodes LE1, LE2 and LE3 overlaps the slit SL. For this reason, external light L which enters the slit SL passes through the slit SL to the lower side without being blocked by the partition 6 or the lower electrode LE1, LE2 or LE3.

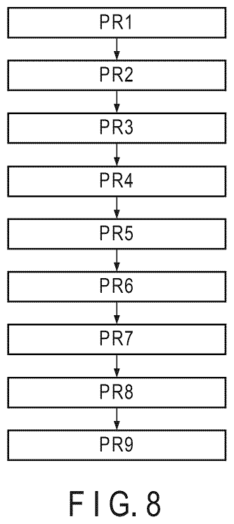

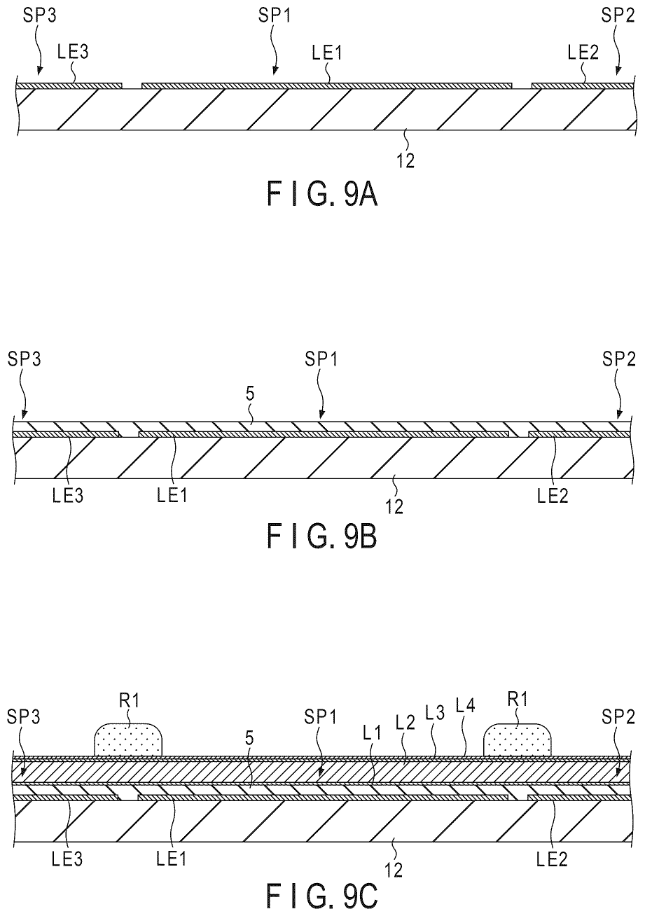

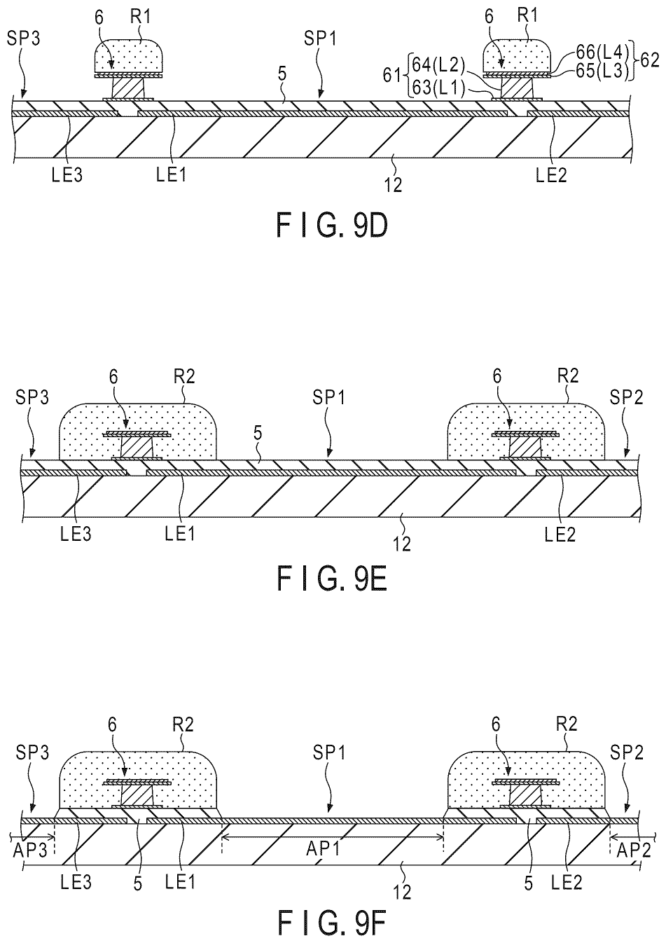

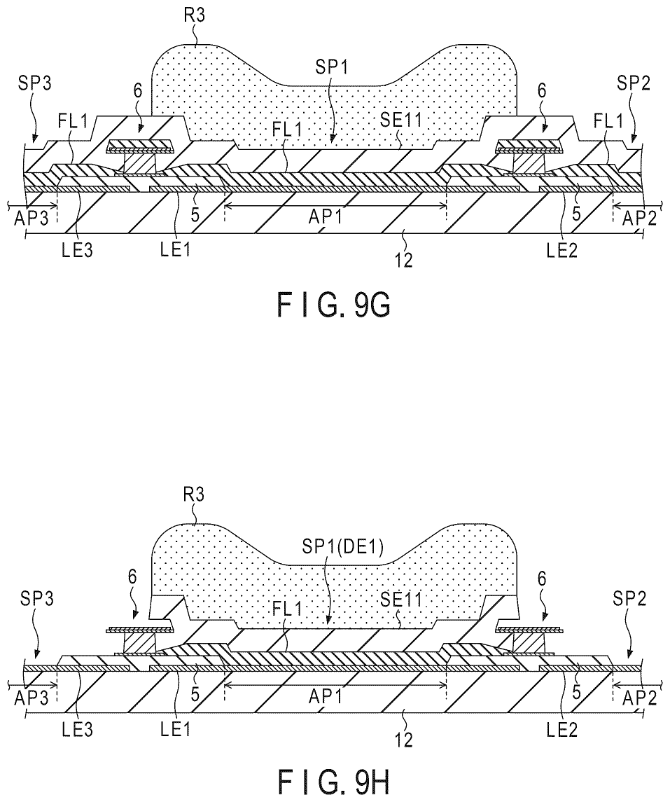

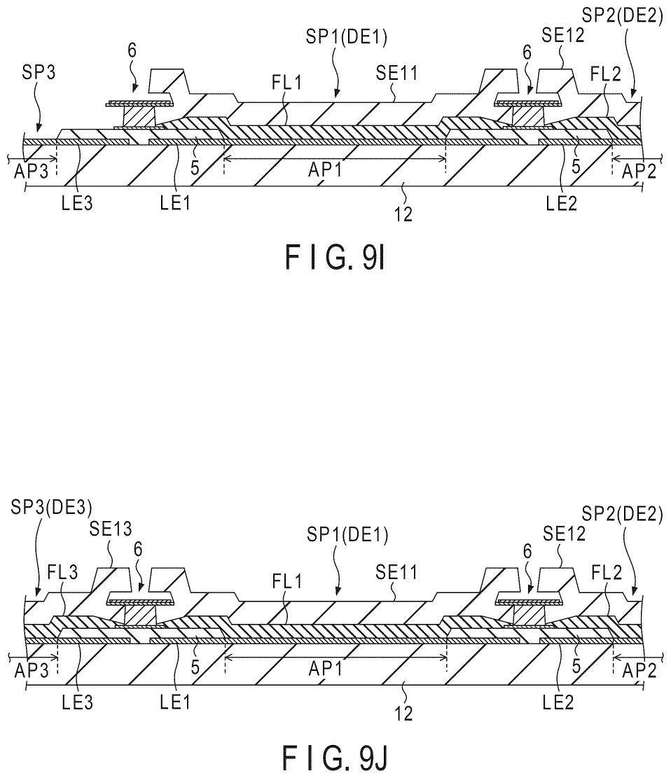

Now, this specification explains an example of the manufacturing method of the display device DSP. FIG. 8 is a flowchart showing an example of the manufacturing method of the display device DSP. Each of FIG. 9A to FIG. 9J is a schematic cross-sectional view showing the manufacturing process of the display device DSP. In FIG. 9A to FIG. 9J, the display area DA is mainly looked at, and the elements located under the organic insulating layer 12 are omitted.

To form the display device DSP, first, the circuit layer 11 and the organic insulating layer 12 are formed on the substrate 10 (process PR1 in FIG. 8). Subsequently, as shown in FIG. 9A, the lower electrodes LE1, LE2 and LE3 are formed on the organic insulating layer 12 (process PR2 in FIG. 8).

Subsequently, as shown in FIG. 9B, the rib layer 5 which covers the lower electrodes LE1, LE2 and LE3 is formed (process PR3 in FIG. 8). At this time, the pixel aperture AP1, AP2 or AP3 is not provided in the rib layer 5. The rib layer 5 may be formed by chemical vapor deposition (CVD).

After the formation of the rib layer 5, a process for forming the partition 6 is performed (process PR4 in FIG. 8). In process PR4, as shown in FIG. 9C, a first layer L1 which is processed so as to be the bottom layer 63, a second layer L2 which is processed so as to be the stem layer 64, a third layer L3 which is processed so as to be the first top layer 65 and a fourth layer L4 which is processed so as to be the second top layer 66 are formed in order. Further, a resist R1 is provided on the fourth layer L4. The resist R1 has been patterned into the shape of the partition 6. The first layer L1, the second layer L2, the third layer L3 and the fourth layer L4 are formed by, for example, sputtering.

Subsequently, the first layer L1, the second layer L2, the third layer L3 and the fourth layer L4 are patterned using the resist R1 as a mask. For example, the first layer L1 is formed of titanium nitride. The second layer L2 is formed of aluminum. The third layer L3 is formed of titanium. The fourth layer L4 is formed of ITO. In this case, the above patterning may include wet etching for removing the portion of the fourth layer L4 exposed from the resist R1, dry etching for removing the portions of the first, second and third layers L1, L2 and L3 exposed from the resist R1, and wet etching for reducing the width of the second layer L2.

Through process PR4, as shown in FIG. 9D, the partition 6 is formed in the display area DA. It should be noted that the slits SL described above are also formed by the above patterning. After the formation of the partition 6, the resist R1 is removed (peeled off). In the above wet etching for reducing the width of the second layer L2, the second top layer 66 (fourth layer L4) could be slightly corroded. When this corrosion occurs, the width of the second top layer 66 becomes less than that of the first top layer 65.

Subsequently, a process for providing the pixel apertures AP1, AP2 and AP3 is performed (process PR5 in FIG. 8). In this process PR5, as shown in FIG. 9E, a resist R2 which covers the partition 6 is formed. Further, dry etching for the rib layer 5 is performed using the resist R2 as a mask. By this process, as shown in FIG. 9F, the pixel apertures AP1, AP2 and AP3 from which the lower electrodes LE1, LE2 and LE3 are exposed are formed in the rib layer 5. After the dry etching described above, the resist R2 is removed (peeled off).

After process PR5, a process for forming the display element DE1 is performed (process PR6 in FIG. 8). To form the display element DE1, first, as shown in FIG. 9G, the stacked film FL1 and the sealing layer SE11 are formed. The stacked film FL1 includes, as shown in FIG. 3, the organic layer OR1 which is in contact with the lower electrode LE1 through the pixel aperture AP1, the upper electrode UE1 which covers the organic layer OR1 and the cap layer CP1 which covers the upper electrode UE1. The organic layer OR1, the upper electrode UE1 and the cap layer CP1 may be formed by, for example, vapor deposition. The sealing layer SE11 may be formed by, for example, CVD.

The stacked film FL1 and the sealing layer SE11 are formed in the surrounding area SA as well as the display area DA. The stacked film FL1 is divided into a plurality of portions by the partition 6 having an overhang shape. The sealing layer SE11 continuously covers the portions into which the stacked film FL1 is divided, and the partition 6.

Subsequently, the stacked film FL1 and the sealing layer SE11 are patterned. In this patterning, as shown in FIG. 9G, a resist R3 is provided on the sealing layer SE11. The resist R3 covers subpixel SP1 and part of the partition 6 around subpixel SP1.

Subsequently, an etching process using the resist R3 a mask is performed. By this process, as shown in FIG. 9H, the portions of the stacked film FL1 and the sealing layer SE11 exposed from the resist R3 are removed. By this process, the display element DE1 is formed in subpixel SP1. This etching process includes wet etching and dry etching processes which are performed in order for the sealing layer SE11, the cap layer CP1, the upper electrode UE1 and the organic layer OR1. After these etching processes, the resist R3 is removed (peeled off).

It should be noted that the stacked film FL1 located under the sealing layer SE11 on the partition 6 is also removed in wet etching for the stacked film FL1. By this process, a gap is formed between the sealing layer SE11 located above the partition 6 and the partition 6. Since the stacked film FL1 which constitutes the display element DE1 is completely surrounded by the sealing layer SE11 and the partition 6, this stacked film FL1 is not corroded by the wet etching described above.

Before the wet etching, the stacked film FL1 is formed in portions corresponding to the gaps GP1 and GP2 shown in FIG. 6 as well. The stacked film FL1 in these portions is removed as the etchant permeates the stacked film FL1 from the vicinity of the end portion of the sealing layer SE11 to the lower side of the sealing layer SE11 in the wet etching. Thus, the gaps GP1 and GP2 are formed.

After process PR6, a process for forming the display element DE2 is performed (process PR7 in FIG. 8). The display element DE2 can be formed by a procedure similar to that of the display element DE1. Specifically, to form the display element DE2, the stacked film FL2 and the sealing layer SE12 are formed in the entire display area DA and surrounding area SA. The stacked film FL2 includes, as shown in FIG. 3, the organic layer OR2 which is in contact with the lower electrode LE2 through the pixel aperture AP2, the upper electrode UE2 which covers the organic layer OR2 and the cap layer CP2 which covers the upper electrode UE2.

The organic layer OR2, the upper electrode UE2 and the cap layer CP2 may be formed by, for example, vapor deposition. The sealing layer SE12 may be formed by, for example, CVD. The stacked film FL2 is divided into a plurality of portions by the partition 6 having an overhang shape. The sealing layer SE12 continuously covers the portions into which the stacked film FL2 is divided, and the partition 6. By patterning these stacked film FL2 and sealing layer SE2, the display element DE2 is formed in subpixel SP2 as shown in FIG. 9I.

After process PR7, a process for forming the display element DE3 is performed (process PR8 in FIG. 8). The display element DE3 can be formed by a procedure similar to the procedures of the display elements DE1 and DE2. Specifically, to form the display element DE3, the stacked film FL3 and the sealing layer SE13 are formed in the entire display area DA and surrounding area SA. The stacked film FL3 includes, as shown in FIG. 3, the organic layer OR3 which is in contact with the lower electrode LE3 through the pixel aperture AP3, the upper electrode UE3 which covers the organic layer OR3 and the cap layer CP3 which covers the upper electrode UE3.

The organic layer OR3, the upper electrode UE3 and the cap layer CP3 may be formed by, for example, vapor deposition. The sealing layer SE13 may be formed by, for example, CVD. The stacked film FL3 is divided into a plurality of portions by the partition 6 having an overhang shape. The sealing layer SE13 continuously covers the portions into which the stacked film FL3 is divided, and the partition 6. By patterning these stacked film FL3 and sealing layer SE13, the display element DE3 is formed in subpixel SP3 as shown in FIG. 9J.

After process PR8, the resin layer RS1, the sealing layer SE2 and the resin layer RS2 are formed in order (process PR9 in FIG. 8). To form the resin layers RS1 and RS2, for example, an ink-jet method may be used. To form the sealing layer SE2, for example, CVD may be used.

Now, this specification explains some effects obtained from the display device DSP according to the embodiment.

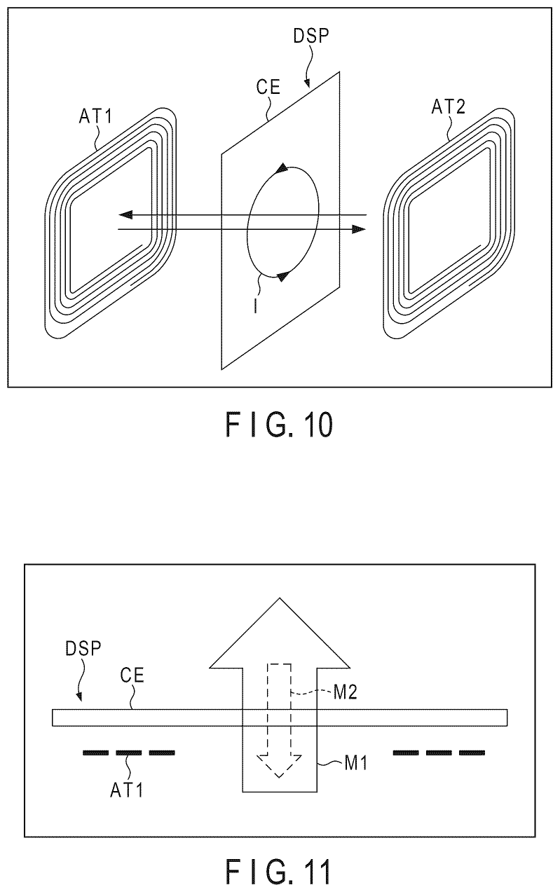

FIG. 10 and FIG. 11 are diagrams for explaining the effects of the display device DSP according to the embodiment. An electronic device on which the display device DSP is mounted may comprise an antenna AT1 for near field communication (NFC). The antenna AT1 is provided so as to, for example, face the rear side of the display device DSP (in other words, the lower surface of the substrate 10 shown in FIG. 3) and wirelessly communicates with the antenna AT2 of another electronic device through the display device DSP.

At the time of wireless communication between the antennas AT1 and AT2, eddy current I is generated in the common electrode CE by magnetic field M1 formed by the antenna AT1. By eddy current I, magnetic field M2 which negates magnetic field M1 is formed, and the signal strength is attenuated. Thus, when wireless communication is performed via the display device DSP, the communication sensitivity could be decreased. In particular, when the partition 6 mainly formed of a metal material and having a grating shape is formed in the entire display area DA, the resistance of the common electrode CE is low. Thus, a large eddy current I occurs, thereby generating a strong magnetic field M2. Thus, the communication sensitivity is easily decreased.

To the contrary, in the embodiment, the common electrode CE is divided into a plurality of segments SG by the slits SL. In this case, a large eddy current is not easily generated in the common electrode CE. Thus, the decrease in communication sensitivity can be prevented. Eddy current could be generated in each segment SG. However, the effect caused to communication sensitivity by this eddy current is tiny compared to eddy current I generated in the entire part of a common electrode CE which is not divided.

Electronic devices on which the display device DSP is mounted may comprise an optical sensor such as an illumination sensor which detects external light. When such an optical sensor is provided on the rear side of the display device DSP, translucency is required in the display device DSP.

However, each of the lower electrodes LE1, LE2 and LE3 includes the reflective layer described above. In addition, the partition 6 which is at least partly formed of a metal material has light-shielding properties. For this reason, the light which is made incident on the display surface of the display device DSP could be mostly reflected or blocked without being transmitted to the rear side.

To the contrary, when the slits SL are provided in the partition 6 like the embodiment, as in the case of external light L shown in FIG. 6 and FIG. 7, part of the light which is made incident on the display surface is transmitted to the rear side of the display device DSP through the slits SL. By this configuration, the translucency of the display device DSP can be enhanced.

In this manner, the embodiment can provide the display device DSP which is compatible with an antenna for wireless communication and an optical sensor. Moreover, as explained below, the embodiment can improve the yield of the display device DSP.

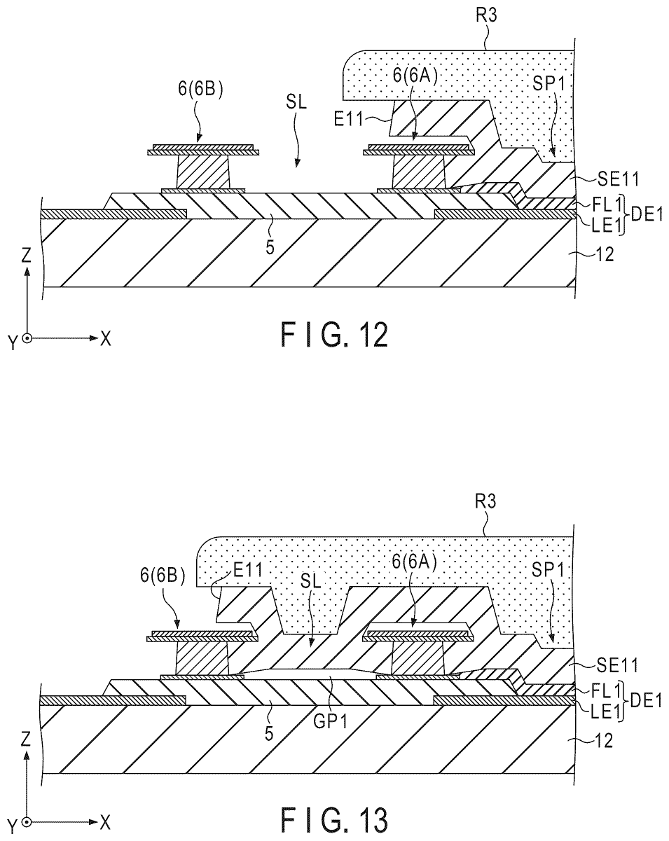

FIG. 12 is a schematic cross-sectional view of a configuration according to a comparative example of the embodiment. FIG. 13 is a schematic cross-sectional view for explaining the effect of the embodiment. The sections of these figures are the sections immediately after the display element DE1 is formed in a portion similar to that of FIG. 6, and include subpixel SP1, the partitions 6A and 6B and the slit SL.

In the comparative example shown in FIG. 12, the end portion E11 of the sealing layer SE11 is located above the partition 6A, and the slit SL is not covered with the sealing layer SE11. In this case, a large step having a complicated shape is formed near the slit SL by the end portion E11 and the partition 6A. By this configuration, an air bubble is easily generated inside the slit SL.

If process PR7 for forming the display element DE2 is performed in a state where an air bubble is generated, the air bubble bursts at the time of the reduced-pressure drying of the resist for patterning the stacked film FL2 and the sealing layer SE12. Thus, the area which should be covered with the resist under normal conditions is exposed. A similar situation may occur in the subsequent process PR8.

To the contrary, as shown in FIG. 13, in the display device DSP of the embodiment, the sealing layer SE11 covers the slit SL near subpixel SP1. Thus, the step of the vicinity of the slit SL and the complicated shape formed by the partitions 6A and 6B are eased. Air bubbles are not easily generated in the slit SL. This configuration can prevent the burst of the resists formed in processes PR7 and PR8. As a result, the yield of the display device DSP is improved.

When the stacked film FL1 is formed under the sealing layer SE11 in the slit SL, the partitions 6A and 6B may be electrically continuous with each other by the upper electrode UE1. In this case, the prevention of the eddy current described above is disturbed. In addition, the transmittance of the slit SL may be reduced by the stacked film FL1.

To the contrary, in the embodiment, the stacked film FL1 located under the sealing layer SE11 is also removed by the etching of the stacked film FL1 as described above. By this configuration, the conduction of the segments SG which are adjacent to each other via the slit SL is prevented, and further, the transmittance in the slit SL can be increased.

### Second Embodiment

A second embodiment is explained. With regard to configurations which are not particularly referred to in this embodiment, configurations similar to those of the first embodiment can be applied.

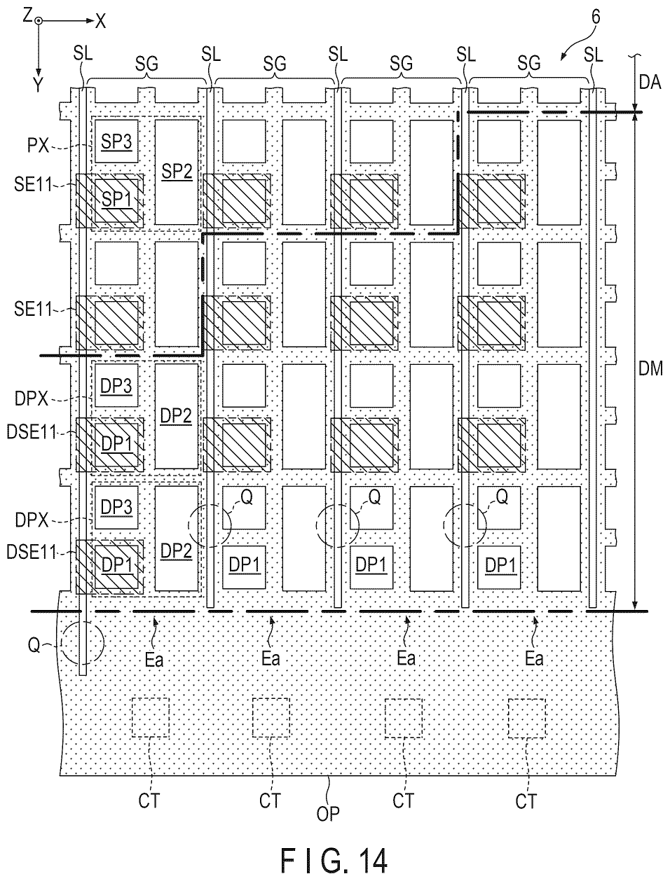

FIG. 14 is a schematic plan view showing a configuration according to the second embodiment. In this figure, the vicinity of the first end portion Ea of each segment SG (see FIG. 4) is particularly looked at.

In this embodiment, a dummy pixel area DM is provided outside a display area DA. The dummy pixel area DM is part of the surrounding area SA described above. The dummy pixel area DM includes a plurality of dummy pixels DPX and surrounds the display area DA. From another viewpoint, the dummy pixels DPX are provided so as to surround the pixels PX provided in the display area DA.

For example, each dummy pixel DPX includes dummy subpixels DP1, DP2 and DP3. Dummy subpixels DP1, DP2 and DP3 have structures similar to those of subpixels SP1, SP2 and SP3, respectively. However, dummy subpixels DP1, DP2 and DP3 are configured not to emit light. This configuration may be realized by, for example, disconnecting part of the pixel circuit 1 in each of dummy subpixels DP1, DP2 and DP3. Pixel apertures AP1, AP2 and AP3 may be omitted in dummy subpixels DP1, DP2 and DP3, respectively.

Part of a partition 6 is located in the dummy pixel area DM and surrounds dummy subpixels DP1, DP2 and DP3. The shape and layout of the aperture of the partition 6 in each of dummy subpixels DP1, DP2 and DP3 are similar to those of the aperture of the partition 6 in a corresponding subpixel SP1, SP2 or SP3.

Each slit SL is partly located in the dummy pixel area DM. In other words, each slit SL is formed so as to range from the display area DA to the dummy pixel area DM.

A dummy sealing layer DSE11 is provided in at least one of dummy subpixels DP1. In the example of FIG. 14, the dummy sealing layer DSE11 is provided in at least dummy subpixel DP1 of each dummy pixel DPX which is adjacent to the display area DA.

Further, like the three dummy subpixels DP1 located in the lower part of the figure, the dummy sealing layer DSE11 may not be provided in at least one of the dummy subpixels DP1 provided in the outermost circumference of the dummy pixel area DM.

The dummy sealing layer DSE11 is formed in process PR6 (see FIG. 8) together with the sealing layer SE11. In dummy subpixel DP1, a stacked film FL1 is provided under the dummy sealing layer DSE11.

Although omitted in FIG. 14, sealing layers SE12 and SE13 are provided in subpixels SP2 and SP3, respectively. In dummy subpixels DP2 and DP3, dummy sealing layers formed by the same processes as the sealing layers SE12 and SE12 are provided, respectively. The planar shapes of these dummy sealing layers are similar to those of the sealing layers SE12 and SE13 shown in FIG. 5.

The dummy sealing layer DSE11 overlaps a slit SL in a manner similar to that of the sealing layer SE11. Like the slit SL located at the right end of FIG. 14, a slit SL which does not overlap the dummy sealing layer DSE11 may be present.

In the example of FIG. 14, the partition 6 further includes an outer circumferential portion OP located outside the dummy pixel area DM. The outer circumferential portion OP is connected to the first end portion Ea of each segment SG. The outer circumferential portion OP does not have an aperture such as the apertures of dummy subpixels DP1, DP2 and DP3. The outer circumferential portion OP is connected to the power supply line PW shown in FIG. 4 via a plurality of contact portions CT.

Like the slit SL located at the left end of FIG. 14, at least one slit SL may extend to the outer circumferential portion OP. Further, like the other slits SL in FIG. 14, at least one slit SL may not extend to the outer circumferential portion OP.

For example, there is a possibility that a resist bursts as described above in a slit SL spaced apart from the dummy sealing layer DSE11 like position Q shown by the chained circle in FIG. 14. Even in this case, when the display area DA is surrounded by dummy subpixels DP1 in which the dummy sealing layers DSE11 are provided, position Q is spaced apart from the display area DA. As a result, even if the resist bursts, the effect caused by this burst does not easily act on the display area DA.

### Third Embodiment

A third embodiment is explained. With regard to configurations which are not particularly referred to in this embodiment, configurations similar to those of each of the embodiments described above can be applied.

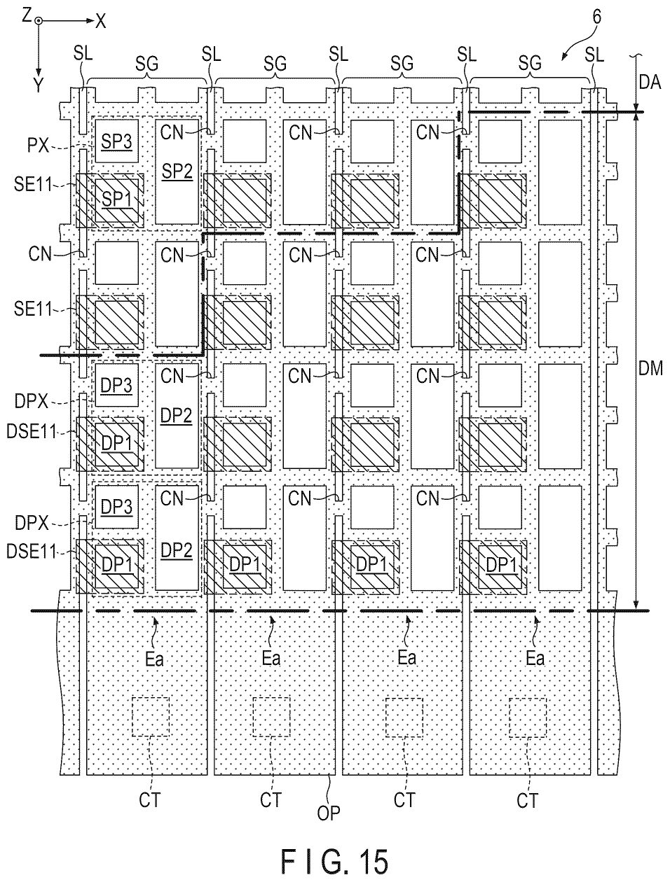

FIG. 15 is a schematic plan view showing a configuration according to the third embodiment. In this figure, in a manner similar to that of FIG. 14, the vicinity of the first end portion Ea of each segment SG is particularly looked at.

In the example of FIG. 15, each slit SL reaches the outer edge of an outer circumferential portion OP. Further, in the example of FIG. 15, a partition 6 includes a plurality of connection portions CN each of which connects segments SG which are adjacent to each other across a corresponding slit SL.

For example, each connection portion CN is provided between two sealing layers SE11 in a Y-direction (the extension direction of the slits SL). From another viewpoint, each connection portion CN is provided at a position adjacent to subpixel SP3 in an X-direction. By providing these connection portions CN, the resistance of the partition 6 can be reduced.

It should be noted that, if the connection portions CN are provided in all of the slits SL, the effect of preventing the eddy current described above is reduced. Therefore, it is preferable that a slit SL in which no connection portion CN is provided should be present like the slit SL located at the right end in FIG. 15.

### Fourth Embodiment

A fourth embodiment is explained. With regard to configurations which are not particularly referred to in this embodiment, configurations similar to those of each of the embodiments described above can be applied.

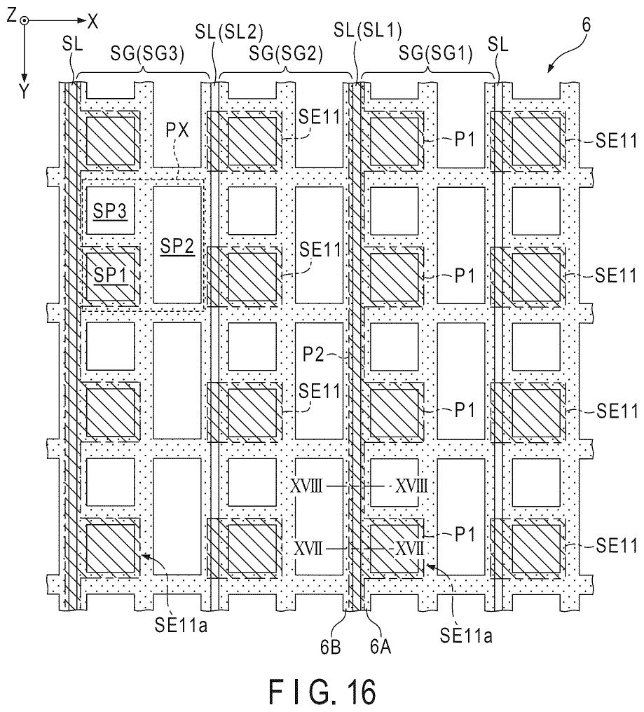

FIG. 16 is a schematic plan view showing a configuration according to the fourth embodiment. In a manner similar to that of FIG. 5, elements such as sealing layers SE12 and SE13 are omitted in FIG. 16.

In this embodiment, in addition to the sealing layer SE11 described above, a sealing layer SE11a is provided in a display area DA. The sealing layer SE11a is formed in process PR6 (see FIG. 8) together with the sealing layer SE11.

The sealing layer SE11a includes a plurality of first portions P1 which overlap subpixels SP1, and a second portion P2 which connects these first portions P1. The second portion P2 overlaps a slit SL and extends in a Y-direction (the extension direction of the slit SL).

Here, this specification focuses attention on three segments (first to third segments) SG1, SG2 and SG3 separated by two slits SL1 and SL2. The segment SG1 has a partition (first partition) 6A along the slit SL1. The segment SG2 has a partition (second partition) 6B along the slit SL1.

In the example of FIG. 16, the sealing layer SE11a is provided so as to overlap the slit SL1. To the contrary, the sealing layers SE11 which overlap the slit SL2 are not connected to each other in the second portion P2, and are spaced apart from each other. In the example of FIG. 16, these sealing layer SE11 and sealing layer SE11a are alternately provided in an X-direction.

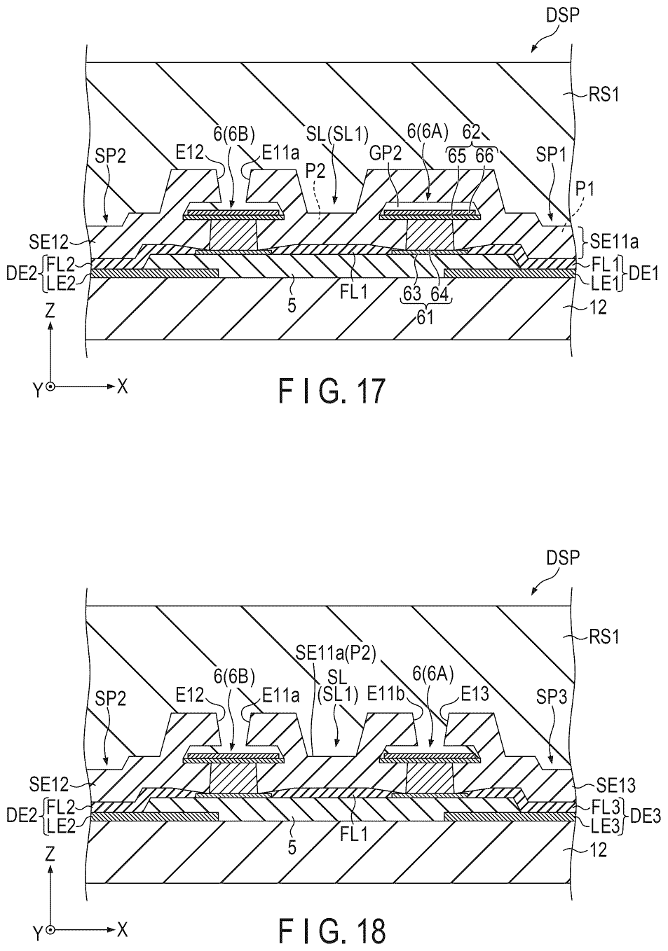

FIG. 17 is the schematic cross-sectional view of a display device DSP along the XVII-XVII line of FIG. 16. FIG. 18 is the schematic cross-sectional view of the display device DSP along the XVIII-XVIII line of FIG. 16. In these figures, the elements located under an organic insulating layer 12 and the elements located above a resin layer RS1 are omitted.

The section shown in FIG. 17 is generally similar to that shown in FIG. 5. Specifically, the first portion P1 of the sealing layer SE11a covers a display element DE1. The second portion P2 of the sealing layer SE11a covers the slit SL1 and is partly located inside the slit SL1. An end portion Ella of the second portion P2 is located above the partition 6B.

In the section of FIG. 18, the second portion P2 is located between subpixels SP2 and SP3 in the X-direction (width direction). An end portion Ella of the second portion P2 is located above the partition 6B, and the other end portion E11b is located above the partition 6A. The end portion Ella faces an end portion E12 of the sealing layer SE12. The end portion E11b faces an end portion E13 of the sealing layer SE13.

In this embodiment, the slit SL1 is covered with the sealing layer SE11a as a whole. For this reason, when the sealing layers SE11 and SE11a are formed, an etchant does not easily permeate the lower side of the sealing layer SE11a in the slit SL1. By this configuration, in the examples of FIG. 17 and FIG. 18, a stacked film FL1 is provided under the sealing layer SE11a (second portion P2) in the slit SL1. As another example, a gap GP1 similar to that of FIG. 6 may be formed under the sealing layer SE11a.

As the slit SL1 is covered with the sealing layer SE11a as a whole, the generation of air bubbles described above is more effectively prevented in the slit SL1. If the stacked film FL1 is formed in the slit SL1, the segments SG1 and SG2 may be electrically continuous with each other by an upper electrode UE1 included in the stacked film FL1. Thus, if all of the slits SL provided in the display area DA have the same structure as the slit SL1 shown in FIG. 17 and FIG. 18, the effect of preventing eddy current described above is reduced.

Therefore, it is preferable that a slit SL which is partially covered with the sealing layer SE11 like the slit SL2 shown in FIG. 16 and a slit SL which is not entirely covered with the sealing layer SE11 should be present.

### Fifth Embodiment

A fifth embodiment is explained. With regard to configurations which are not particularly referred to in this embodiment, configurations similar to those of each of the embodiments described above can be applied.

The first embodiment assumes a case where display elements DE1, DE2 and DE3 are formed in this order. The present embodiment assumes a case where the display element DE2 is formed firstly, and the display elements DE1 and DE3 are subsequently formed. In this case, resists may burst as described above when the display elements DE1 and DE3 are formed. For this reason, as exemplarily described below, at least part of slits SL should be preferably filled with a sealing layer SE12.

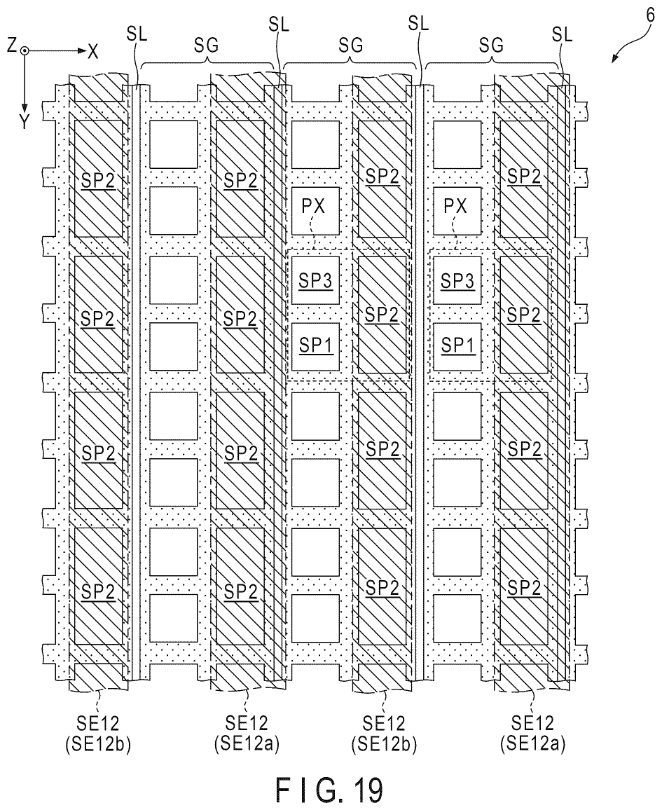

FIG. 19 is a schematic plan view showing a configuration according to the fifth embodiment. In the example of this figure, each sealing layer SE12 has a belt-like shape which continuously covers subpixels SP2 arranged in a Y-direction.

A plurality of sealing layers SE12 provided in a display area DA include sealing layers SE12a which overlap the slits SL, and sealing layers SE12b which do not overlap the slits SL. These sealing layers SE12a and SE12b are, for example, alternately arranged in an X-direction.

In each slit SL overlapping the sealing layer SE12a, a stacked film FL2 may be formed under the sealing layer SE12a. In this case, the adjacent segment SG may be brought into conduction by an upper electrode UE2 included in the stacked film FL2. Thus, if all of the sealing layers SE12 in the display area DA are the sealing layers SE12a, the effect of preventing eddy current described above is reduced.

Therefore, as shown in FIG. 19, the sealing layer SE12b which does not overlap the slit SL should be preferably provided. It should be noted that the sealing layers SE12a and SE12b are not necessarily alternately provided.

In the present embodiment, subpixel SP2, the display element DE2 and the sealing layer SE12 are examples of the first subpixel, the first display element and the first sealing layer, respectively. Subpixel SP1, the display element DE1 and the sealing layer SE11 are examples of the second subpixel, the second display element and the second sealing layer, respectively. Subpixel SP3, the display element DE3 and the sealing layer SE13 are examples of the third subpixel, the third display element and the third sealing layer, respectively.

When the display element DE3 is formed firstly, the sealing layer SE13 may be provided in the same form as the sealing layer SE11 of the first to fourth embodiments. This configuration can prevent the phenomenon in which resists burst when the display elements DE1 and DE2 are formed as described above.

The configurations of the first to fifth embodiments may be combined with each other as appropriate. For example, the configurations of the dummy pixel area DM, the outer circumferential portion OP and the connection portions CN shown in the second and third embodiments can be also applied to the first, fourth and fifth embodiments.

All of the display devices that can be implemented by a person of ordinary skill in the art through arbitrary design changes to the display device described above as each embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or adding or omitting a step or changing the condition of a step, all of the modifications fall within the scope of the present invention as long as they are in keeping with the spirit of the invention.

Further, other effects which may be obtained from each embodiment and are self-explanatory from the descriptions of the specification or can be arbitrarily conceived by a person of ordinary skill in the art are considered as the effects of the present invention as a matter of course.

What is claimed is:

1. A display device comprising:
a display area including a plurality of subpixels;
a partition which includes a conductive lower portion and an upper portion having an end portion protruding from a side surface of the lower portion, and surrounds each of the subpixels;
a plurality of display elements which are provided in the subpixels, respectively, and each of which includes an organic layer which emits light based on application of voltage; and
a plurality of sealing layers which are formed of an inorganic insulating material and cover the display elements, respectively, wherein
the partition includes a plurality of segments separated by a slit, and
at least one of the sealing layers overlaps at least part of the slit as seen in plan view.

2. The display device of claim 1, wherein
the subpixels include first to third subpixels,
the display elements include first to third display elements which are provided in the first to third subpixels, respectively, and which emit light exhibiting different colors,
the sealing layers include first to third sealing layers which cover the first to third display elements, respectively,
the first sealing layer overlaps at least part of the slit as seen in plan view, and
at least one of the second sealing layer and the third sealing layer is spaced apart from the slit as seen in plan view.

3. The display device of claim 2, wherein
the first sealing layer intersects with the slit as seen in plan view.

4. The display device of claim 2, wherein
the first sealing layer includes:
a first portion which covers the first display element; and
a second portion which extends in an extension direction of the slit and covers the slit.

5. The display device of claim 2, wherein
the first subpixels extend in an extension direction of the slit along the slit, and
the first sealing layer extends in the extension direction and continuously covers the first display element provided in each of the first subpixels, and the slit.

6. The display device of claim 1, further comprising a dummy pixel area which includes a plurality of dummy subpixels and is located outside the display area, wherein
part of the partition is located in the dummy pixel area and surrounds each of the dummy subpixels.

7. The display device of claim 6, wherein
the slit is partly located in the dummy pixel area.

8. The display device of claim 7, wherein
the sealing layers include a dummy sealing layer which overlaps at least one of the dummy subpixels and at least part of the slit as seen in plan view.

9. The display device of claim 8, wherein
the partition further includes an outer circumferential portion located outside the dummy pixel area, and
the slit reaches the outer circumferential portion.

10. The display device of claim 9, wherein
in, of the dummy subpixels, at least one dummy subpixel provided in an outermost circumference of the dummy pixel area, the dummy sealing layer is not provided.

11. The display device of claim 9, wherein
the slit reaches an outer edge of the outer circumferential portion.

12. The display device of claim 1, wherein
the partition further includes a connection portion which connects the segments across the slit.

13. The display device of claim 12, wherein
the connection portion is provided between the two sealing layers in an extension direction of the slit.

14. A display device comprising:
a first subpixel and a second subpixel;
a partition which includes a conductive lower portion and an upper portion having an end portion protruding from a side surface of the lower portion, and surrounds the first subpixel and the second subpixel;
first and second display elements which are provided in the first and second subpixels, respectively, and emit light exhibiting different colors; and
first and second sealing layers which are formed of an inorganic insulating material and cover the first and second display elements, respectively, wherein
the partition includes a first segment located on the first subpixel side and a second segment located on the second subpixel side, and the first and second segments are separated by a slit, and
part of the first sealing layer is located inside the slit.

15. The display device of claim 14, wherein
a gap is formed under the first sealing layer in the slit.

16. The display device of claim 14, wherein
the first segment includes a first partition which is adjacent to the slit,
the second segment includes a second partition which is adjacent to the slit, and
both an end portion of the first sealing layer and an end portion of the second sealing layer are located above the second partition.

17. The display device of claim 16, further comprising:
a third subpixel which is adjacent to the first subpixel in an extension direction of the slit, and is adjacent to the second subpixel via the slit in a width direction intersecting with the extension direction;
a third display element provided in the third subpixel; and
a third sealing layer which is formed of an inorganic insulating material and covers the third display element.

18. The display device of claim 17, wherein
an end portion of the third sealing layer is located above the first partition.

19. The display device of claim 17, wherein
the first sealing layer includes:
a first portion which covers the first display element; and
a second portion which extends in the extension direction and is located inside the slit.

20. The display device of claim 19, wherein
part of the second portion is located between the second subpixel and the third subpixel in the width direction.
